(19) United States
(12) Patent Application Publication
(10) Pub. No.: US 2015/0206916 A1
(43) Pub. Date: Jul. 23, 2015

(54) SEMICONDUCTOR DEVICE AND MANUFACTURING METHOD THEREOF

(71) Applicant: XINTEC INC., Taoyuan City (TW)

(72) Inventors: Po-Han LEE, Taipei City (TW); Shu-Ming CHANG, New Taipei City (TW); Tsang-Yu LIU, Zhubei City (TW); Yen-Shih HO, Kaohsiung City (TW); Chien-Hung LIU, New Taipei City (TW)

(21) Appl. No.: 14/595,870

(22) Filed: Jan. 13, 2015

Related U.S. Application Data
(60) Provisional application No. 61/929,431, filed on Jan. 20, 2014.
(60) Provisional application No. 61/970,242, filed on Mar. 25, 2014.

(51) Int. Cl. H01L 27/146; H01L 31/0203

(52) U.S. Cl. CPC H01L 27/14632; H01L 27/14627; H01L 27/1463; H01L 27/14636; H01L 27/14634; H01L 27/14685; H01L 27/1469; H01L 27/14687; H01L 31/0203

(57) ABSTRACT

A manufacturing method of a semiconductor device includes the following steps. A temporary bonding layer is used to adhere a carrier to a first surface of a wafer. A redistribution layer, an insulating layer, and a conductive structure are formed on a second surface of the wafer opposite to the first surface, such that a semiconductor element is formed. The semiconductor element is diced from the insulating layer to the carrier, such that the semiconductor element forms at least one sub-semiconductor element. UV light is used to irradiate the sub-semiconductor element, such that adhesion of the temporary bonding layer is eliminated. The carrier of the sub-semiconductor element is removed.

### RELATED APPLICATIONS

This application claims priority to U.S. provisional Application Ser. No. 61/929,431, filed Jan. 20, 2014, and U.S. provisional Application Ser. No. 61/970,242, filed Mar. 25, 2014, the disclosures of which are incorporated herein by reference in their entireties.

### BACKGROUND

1. Field of Invention

The present invention relates to a semiconductor device and a manufacturing method of the semiconductor device.

2. Description of Related Art

When a chip used as an image sensor (e.g., a CMOS chip) is manufactured, a glass sheet is often used to cover a surface of a wafer for protection, such that dust is not apt to attach to image sensing areas of the wafer. After the wafer is diced to form a chip, the chip may be used for forming an electronic product. However, a light transmissive sheet is usually disposed on a housing of the electronic product aligned with the chip, and the light transmissive sheet and the glass sheet that is on the surface of the chip have similar protection functions. When the surface of the wafer does not have the glass sheet, although the light transmittance thereof may be increased to improve the image detecting capability of the chip that is formed by dicing the wafer, the thickness of the wafer is significantly thin and thus it is very difficult to move the wafer after ball grid array is formed on the wafer.

In general, the glass sheet may be adhered to the wafer. The glass sheet can provide the wafer with a supporting force, such that the wafer is not apt to be broken due to warpage. After the wafer is ground to reduce its thickness, a ball grid array (BGA) may be formed on the surface of the wafer by a BGA process. Next, the wafer having the glass sheet may be placed on a UV tape contained in an iron frame, and the glass sheet is removed from the wafer for performing a process for cutting the UV tape. After the UV tape is cut, the wafer having the UV tape is placed on a cutting tape contained another iron frame, and UV light is used to irradiate the wafer to remove the UV tape. Finally, a dicing process is performed to the wafer that is on the cutting tape to form plural chips.

After the glass sheet is removed from the wafer, the subsequent processes performed on the wafer are with a wafer level. The image sensing areas of the wafer are easily polluted during these processes, such that the yield rate of the wafer is difficult to be improved. In order to prevent products from being polluted, the processes after the glass sheet is removed from the wafer need to be performed in a clean room, thus increasing the manufacturing cost due to the apparatuses and technical manpower of the clean room. Moreover, the UV tape is expensive, which also increases the manufacturing cost.

### SUMMARY

An aspect of the present invention is to provide a manufacturing method of a semiconductor device.

According to an embodiment of the present invention, a manufacturing method of a semiconductor device includes the following steps. (a) A temporary bonding layer is used to adhere a carrier to a first surface of a wafer. (b) A redistribution layer, an insulating layer, and a conductive structure are formed on a second surface of the wafer opposite to the first surface, such that a semiconductor element is formed. (c) The semiconductor element is diced from the insulating layer to the carrier, such that the semiconductor element forms at least one sub-semiconductor element. (d) UV light is used to irradiate the sub-semiconductor element, such that adhesion of the temporary bonding layer is eliminated. (e) The carrier of the sub-semiconductor element is removed.

In one embodiment of the present invention, the manufacturing method of the semiconductor device further includes adhering the carrier of the semiconductor element to a cutting tape that is surrounded by a frame.

In one embodiment of the present invention, the manufacturing method of the semiconductor device further includes bonding the sub-semiconductor element to a printed circuit board, such that the conductive structure is electrically connected to the printed circuit board.

In one embodiment of the present invention, the first surface of the wafer has a plurality of image sensing elements, and the manufacturing method of the semiconductor device further includes forming a protection layer on the first surface of the wafer, such that the image sensing elements are covered by the protection layer.

In one embodiment of the present invention, the first surface of the wafer has a plurality of image sensing elements, and step (a) further includes controlling contact positions between the temporary bonding layer and the image sensing elements, such that top ends of the image sensing elements are in point contact with the temporary bonding layer.

In one embodiment of the present invention, the first surface of the wafer has a plurality of image sensing elements and a dam element, and step (a) further includes adhering the temporary bonding layer to the dam element, such that the image sensing elements are covered by the temporary bonding layer.

In one embodiment of the present invention, step (c) further includes dicing the semiconductor element from the dam element to the carrier.

In one embodiment of the present invention, a surface of the dam element opposite to the first surface has a protruding portion, and step (a) further includes adhering the temporary bonding layer to the protruding portion, such that the image sensing elements are covered by the temporary bonding layer.

In one embodiment of the present invention, the manufacturing method of the semiconductor device further includes removing the temporary bonding layer of the sub-semiconductor element.

In one embodiment of the present invention, the manufacturing method of the semiconductor device further includes disposing a lens module on the sub-semiconductor element after the temporary bonding layer is removed.

In the aforementioned embodiments of the present invention, after the carrier is adhered to the first surface of the wafer by the temporary bonding layer, the redistribution layer, the insulating layer, and the conductive structure may be formed on the second surface of the wafer. Thereafter, the semiconductor element including the wafer, the redistribution layer, the insulating layer, and the conductive structure can be diced to from at least one sub-semiconductor element. Therefore, in following manufacturing processes, the semiconductor device is manufactured in a chip level.

In the following manufacturing processes after the sub-semiconductor element is formed, since the carrier can remain protecting the chip that is formed by dicing the wafer, the image sensing element on the chip is not apt to be polluted in the following manufacturing processes, such that the yield rate of the chip may be improved. As a result, after the sub-semiconductor element is bonded on the printed circuit board, the UV light is used to irradiate the sub-semiconductor element, and the carrier of the sub-semiconductor element can be removed. Only following manufacturing processes after the carrier is removed need to perform in a clean room, therefore the cost of apparatuses of the clean room and that of technical manpower may be reduced. Moreover, a conventional UV tape can be omitted in the manufacturing method of the semiconductor device, resulting in a decrease in manufacturing costs.

An aspect of the present invention is to provide a semiconductor device.

According to an embodiment of the present invention, a semiconductor device includes a chip, an isolation layer, a redistribution layer, an insulating layer, and a conductive structure. The chip has an electrical pad, a concave hole, a first surface, and a second surface opposite to the first surface. The electrical pad is located on the first surface, the concave hole is located in the second surface, and the first surface of the chip has an image sensing element. The isolation layer is located on the second surface and a side wall of the concave hole. The electrical pad is exposed through the concave hole and the isolation layer. The redistribution layer is located on the isolation layer and the electrical pad, such that the redistribution layer is electrically connected to the electrical pad. The insulating layer is located on the redistribution layer, and a portion of the redistribution layer is exposed through an opening of the insulating layer. The conductive structure is located on the redistribution layer that is in the opening of the insulating layer.

An aspect of the present invention is to provide a semiconductor device.

According to an embodiment of the present invention, a semiconductor device includes a chip, an isolation layer, a redistribution layer, an insulating layer, and a conductive structure. The chip has an electrical pad, a recess, a first surface, and a second surface opposite to the first surface. The electrical pad is located on the first surface, a side wall of the electrical pad is exposed through the recess, and the first surface of the chip has an image sensing element. The isolation layer is located on the second surface and the electrical pad, and the side wall of the electrical pad is exposed through the isolation layer. The redistribution layer is located on the isolation layer and the side wall of the electrical pad, such that the redistribution layer is electrically connected to the electrical pad. The insulating layer is located on the redistribution layer, and a portion of the redistribution layer is exposed through an opening of the insulating layer. The conductive structure is located on the redistribution layer that is in the opening of the insulating layer.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a flow chart of a manufacturing method of a semiconductor device according to one embodiment of the present invention;

FIG. 2 is a schematic view of a carrier after being adhered to a wafer according to one embodiment of the present invention;

FIG. 3 is a schematic view of a redistribution layer, an insulating layer, and a conductive structure after being formed on the wafer shown in FIG. 2;

FIG. 4 is a schematic view of a semiconductor element shown in FIG. 3 when being diced;

FIG. 5 is a schematic view of a sub-semiconductor element shown in FIG. 4 after being extracted from a cutting tape;

FIG. 6 is a schematic view of the sub-semiconductor element shown in FIG. 5 after being bonded to a printed circuit board;

FIG. 7 is a schematic view of the sub-semiconductor element shown in FIG. 6 when the carrier is removed;

FIG. 8 is a schematic view of the sub-semiconductor element shown in FIG. 7 when a temporary bonding layer is removed;

FIG. 9 is a schematic view of the sub-semiconductor element shown in FIG. 8 after the temporary bonding layer is removed;

FIG. 10A is an enlarged cross-sectional view of the sub-semiconductor element shown in FIG. 6;

FIG. 10B is a top view of the semiconductor element shown in FIG. 4;

FIG. 11 is a cross-sectional view of a sub-semiconductor element according to one embodiment of the present invention;

FIG. 12 is a cross-sectional view of a sub-semiconductor element according to one embodiment of the present invention;

FIG. 13 is a cross-sectional view of a sub-semiconductor element according to one embodiment of the present invention;

FIG. 14 is an example of the semiconductor device shown in FIG. 9;

FIG. 15 is another example of the semiconductor device shown in FIG. 9; and

FIG. 16 is another example of the semiconductor device shown in FIG. 9.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

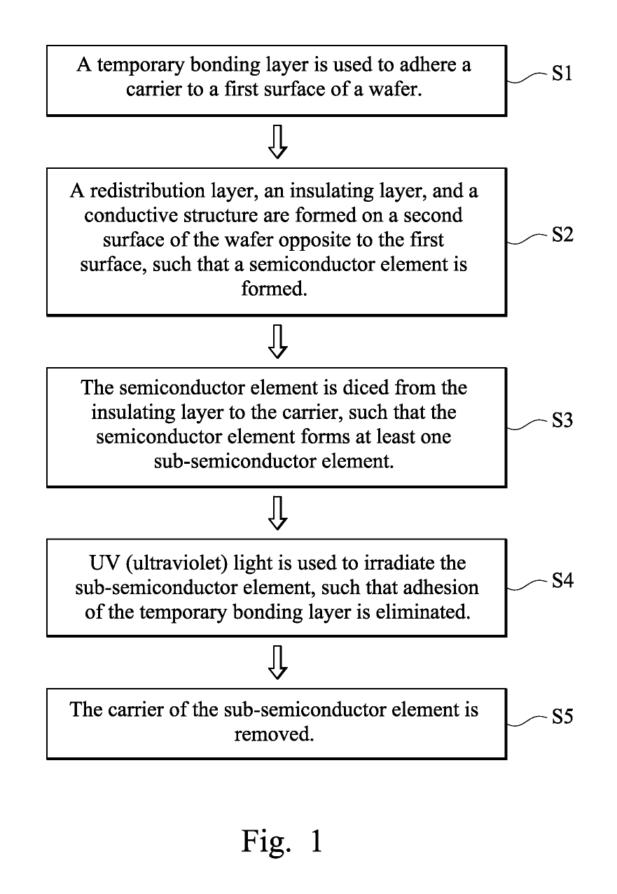

FIG. 1 is a flow chart of a manufacturing method of a semiconductor device according to one embodiment of the present invention. The manufacturing method of the semiconductor device includes the following steps. In step S1, a temporary bonding layer is used to adhere a carrier to a first surface of a wafer. Thereafter, in step S2, a redistribution layer, an insulating layer, and a conductive structure are formed on a second surface of the wafer opposite to the first surface, such that a semiconductor element is formed. Next, in step S3, the semiconductor element is diced from the insulating layer to the carrier, such that the semiconductor element forms at least one sub-semiconductor element. Thereafter, in step S4, UV (ultraviolet) light is used to irradiate the sub-semiconductor element, such that adhesion of the temporary bonding layer is eliminated. Finally, in step S5, the carrier of the sub-semiconductor element is removed. In the following description, the aforesaid steps will be described.

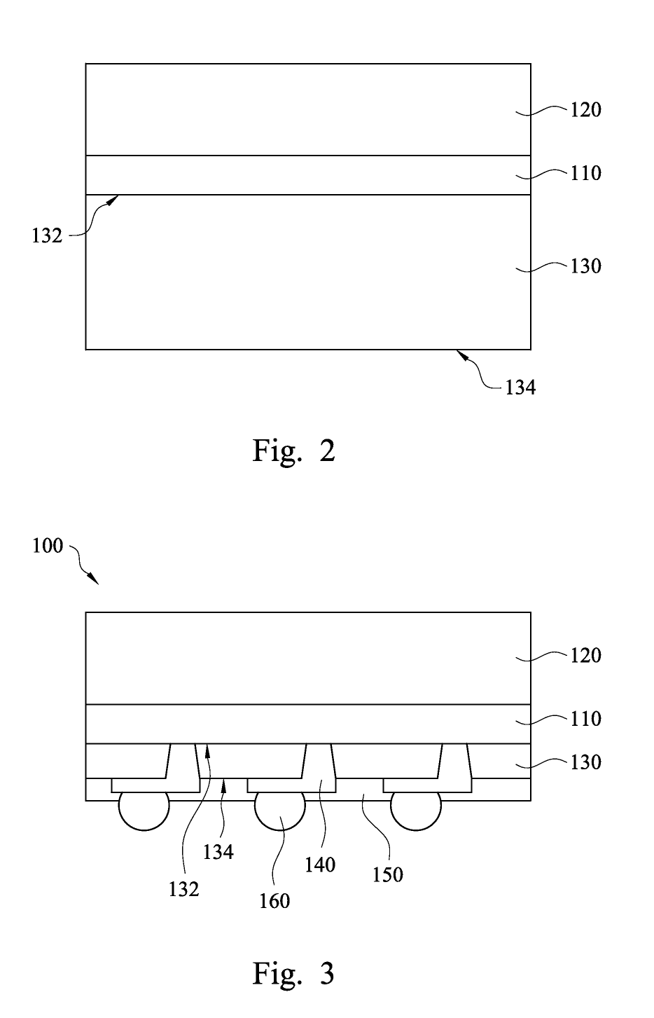

FIG. 2 is a schematic view of a carrier 120 after being adhered to a wafer 130 according to one embodiment of the present invention. The wafer 130 has a first surface 132 and a second surface 134 opposite to the first surface 132. The first surface 132 may have a plurality of image sensing elements, and the second surface 134 is a to-be ground surface. The carrier 120 is adhered to the first surface 132 of the wafer 130 by the temporary bonding layer 110. The carrier 120 may be a glass plate, but the present invention is not limited in this regard. The wafer 130 may be made of a material including silicon, such as a silicon substrate. In this embodiment, the temporary bonding layer 110 includes a material of which the adhesion can be eliminated under UV light.

FIG. 3 is a schematic view of a redistribution layer 140, an insulating layer 150, and a conductive structure 160 after being formed on the wafer 130 shown in FIG. 2. As shown in FIG. 2 and FIG. 3, after the temporary bonding layer 110 adheres the carrier 120 to the wafer 130, the second surface 134 of the wafer 130 may be ground to reduce the thickness of the wafer 130. The carrier 120 may provide a supporting force to the wafer 130, so as to prevent the wafer 130 from being broken during a grinding process. Thereafter, the redistribution layer 140, the insulating layer 150, and the conductive structure 160 may be formed on the ground second surface 134 of the wafer 130. The redistribution layer 140 may be made of a material including aluminum, copper, or other conductive metals. The insulating layer 150 may be a solder mask. The conductive structure 160 may be a conductive protruding block or a solder ball of ball grid array (BGA). In subsequent manufacturing processes, the wafer 130 is a wafer with electrically conductive structures.

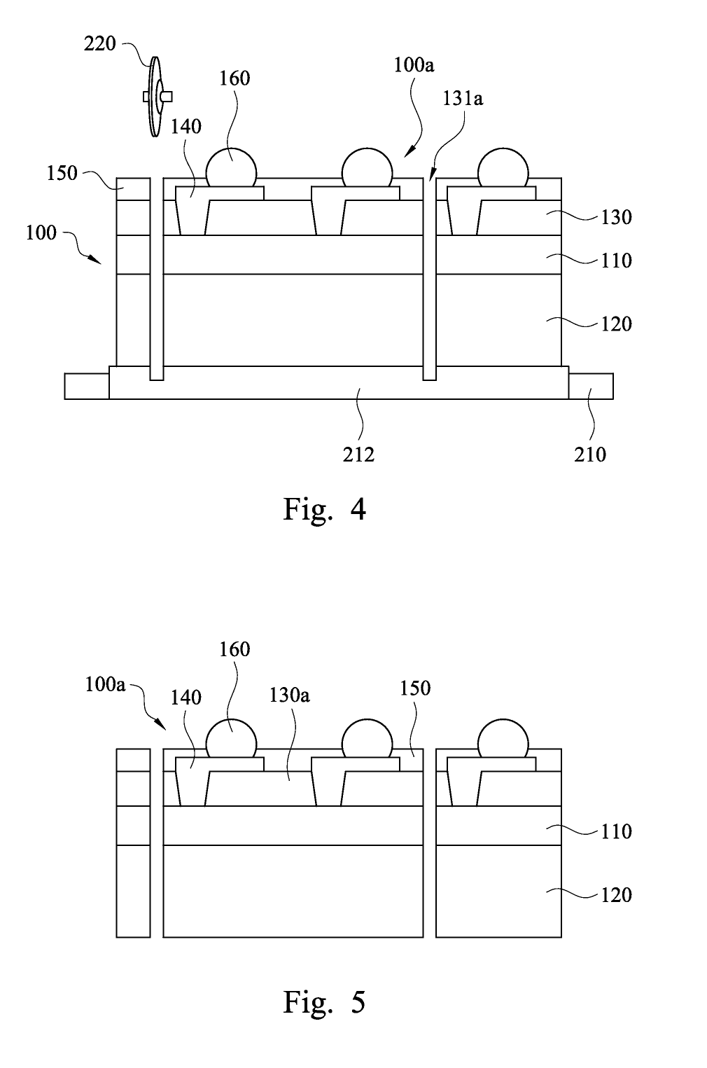

FIG. 4 is a schematic view of a semiconductor element 100 shown in FIG. 3 when being diced. FIG. 5 is a schematic view of a sub-semiconductor element 100a shown in FIG. 4 after being extracted from a cutting tape 212. As shown in FIG. 4 and FIG. 5, after the semiconductor element 100 is formed, the carrier 120 of the semiconductor element 100 may be adhered to a cutting tape 212 that is surrounded by a frame 210. Afterwards, a cutting tool 220 may be used to dice the semiconductor element 110 from the insulating layer 150 to the carrier 120, such that the semiconductor element 100 forms at least one sub-semiconductor element 100a. After the wafer 130 is diced, a chip 130a is formed. The semiconductor element 100 is a wafer level package. The wafer level package is referred to as a semiconductor structure including the entire wafer 130. The sub-semiconductor element 100a is a chip level package. The chip level package is referred to as a semiconductor structure including the chip 130a. In subsequent processes, a semiconductor device is manufactured by utilizing the sub-semiconductor element 100a with a chip level.

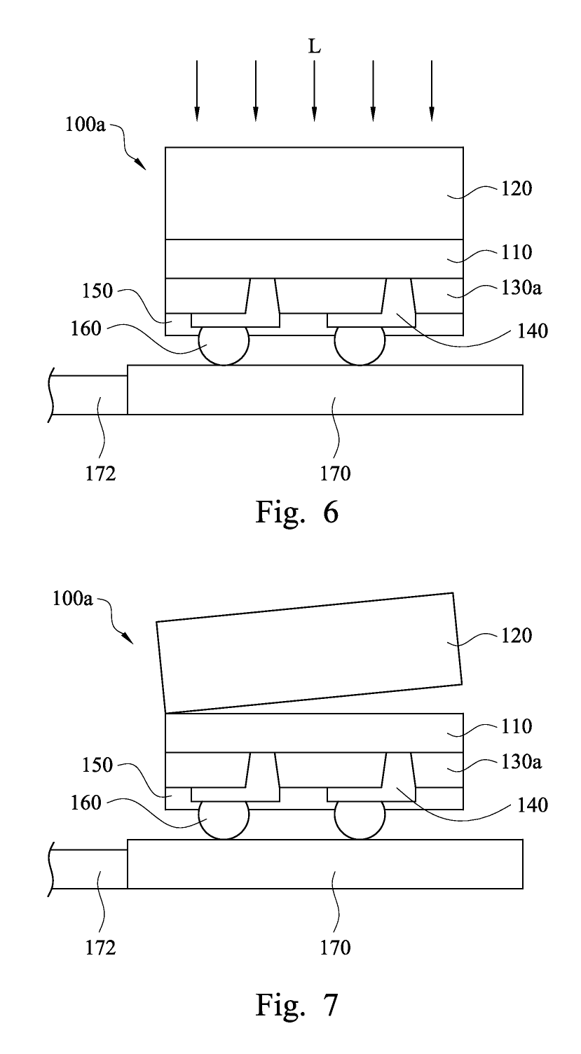

FIG. 6 is a schematic view of the sub-semiconductor element 100a shown in FIG. 5 after being bonded to a printed circuit board 170. After the semiconductor element 100 is diced to form the sub-semiconductor element 100a, the sub-semiconductor element 100a may be bonded to the printed circuit board 170, such that the conductive structure 160 is electrically connected to the printed circuit board 170. The sub-semiconductor element 100a may be fixed on the printed circuit board 170 by utilizing a reflow process of the surface mount technology (SMT). In this embodiment, the printed circuit board 170 has a flexible printed circuit board 172 for connecting external electronic devices.

FIG. 7 is a schematic view of the sub-semiconductor element 100a shown in FIG. 6 when the carrier 120 is removed. As shown in FIG. 6 and FIG. 7, after the sub-semiconductor element 100a is bonded to the printed circuit board 170, UV light L may be used to irradiate the sub-semiconductor element 100a on the printed circuit board 170, such that adhesion of the temporary bonding layer 110 is eliminated. In order to prevent the image sensing element of the chip 130a from being polluted in subsequent processes, the subsequent processes may be performed in a clean room. Thereafter, the carrier 120 of the sub-semiconductor element 100a may be de-bonded from the chip 130a.

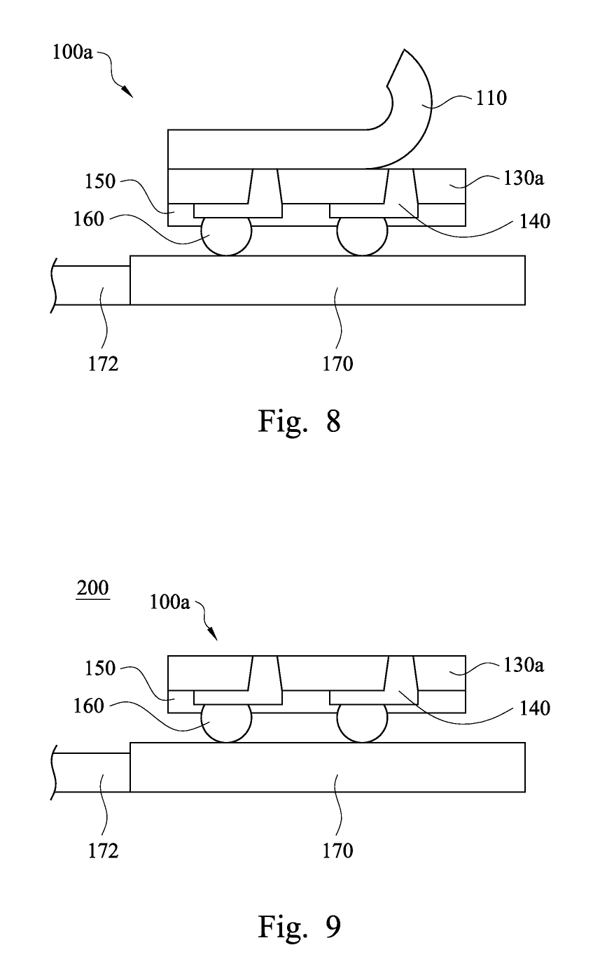

FIG. 8 is a schematic view of the sub-semiconductor element 100a shown in FIG. 7 when the temporary bonding layer 110 is removed. FIG. 9 is a schematic view of the sub-semiconductor element 100a shown in FIG. 8 after the temporary bonding layer 110 is removed. As shown in FIG. 8 and FIG. 9, after the carrier 120 is removed, since the adhesion of the temporary bonding layer 110 is eliminated, an external force or a cleaning process may be used to remove the temporary bonding layer 110 of the sub-semiconductor element 100a. After the temporary bonding layer 110 is removed, a semiconductor device 200 shown in FIG. 9 can be obtained. The sub-semiconductor element 100a of the semiconductor device 200 may be an image sensing chip, such as a front-side illumination CMOS image sensing chip or a backside illumination CMOS image sensing chip.

In a next process, a lens module may be disposed on the semiconductor device 200 or the sub-semiconductor element 100a after the temporary bonding layer is removed.

As shown in FIG. 4 and FIG. 9, in subsequent processes after the sub-semiconductor element 100a is formed, since the carrier 120 still exist to protect the chip 130a that is formed after the wafer 130 is diced, the image sensing element on the chip 130a is not apt to be polluted in the subsequent processes, such that the yield rate of the chip 130a may be improved. As a result, after the sub-semiconductor element 100a is bonded on the printed circuit board 170, the UV light L (see FIG. 6) is used to irradiate the sub-semiconductor element 100a, and the carrier 120 of the sub-semiconductor element 100a can be removed. Because only the processes after the carrier 120 is removed need to be performed in a clean room, the cost of apparatuses and technical manpower of the clean room can be reduced. Moreover, a conventional UV tape can be omitted in the manufacturing method of the semiconductor device 200, thus resulting in a decrease in manufacturing costs.

In the following description, the detailed structure of the sub-semiconductor element 100a shown in FIG. 6 will be described.

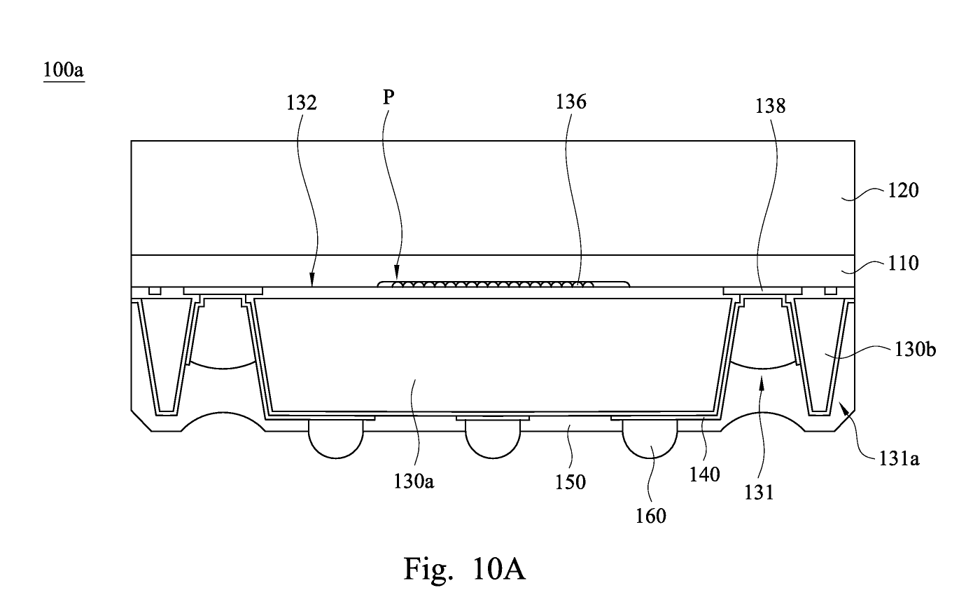

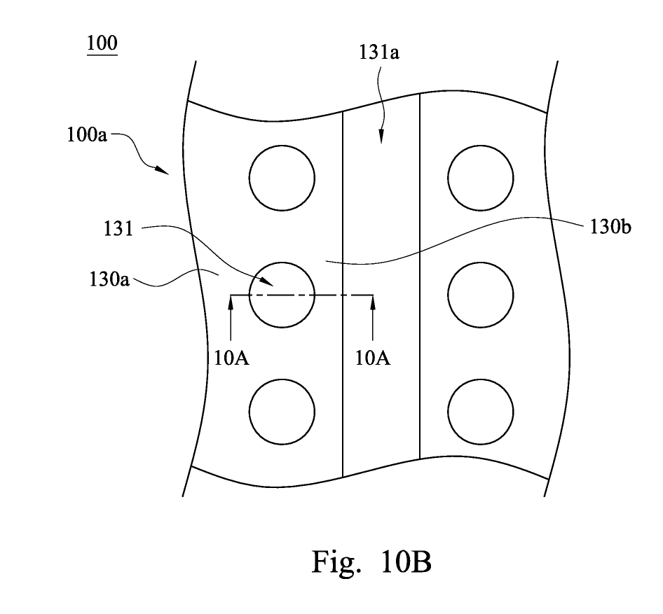

FIG. 10A is an enlarged cross-sectional view of the sub-semiconductor element 100a shown in FIG. 6. As shown in FIG. 2 and FIG. 10A, after the wafer 130 is diced to form the chip 130a, the first surface 132 of the chip 130a has an image sensing element 136. In this embodiment, when the temporary bonding layer 110 is used to adhere the carrier 120 to the first surface 132 of the wafer 130, contact positions between the temporary bonding layer 110 and the image sensing elements 136 may be controlled, such that the top ends P of the image sensing elements 136 are in point contact with the temporary bonding layer 110. In this regard, when UV light irradiates the temporary bonding layer 110 to eliminate the adhesion of the temporary bonding layer 110, since contact areas between the temporary bonding layer 110 and the image sensing elements 136 are small, the temporary bonding layer 110 is easily removed from the chip 130a. However, in another embodiment, the temporary bonding layer 110 may be in surface contact with the image sensing element 136.

FIG. 10B is a top view of the semiconductor element 100 shown in FIG. 4. As shown in FIG. 4 and FIG. 10B, after the semiconductor element 100 is cut by the cutting tool 220, a cut trench 131a is formed by the cutting tool 220, and a side of the cut trench 131a is the sub-semiconductor element 100a shown in FIG. 10A. As shown in FIG. 10A and FIG. 10B, after the cutting process, an edge of the chip 130a of the sub-semiconductor element 100a has the residual cut trench 131a and a residual silicon substrate structure 130b, and the silicon substrate structure 130b is located between the cut trench 131a and the concave hole 131.

It is to be noted that the connection relationship and the materials of the aforementioned elements will not be repeated. In the following description, other types of the sub-semiconductor element will be described.

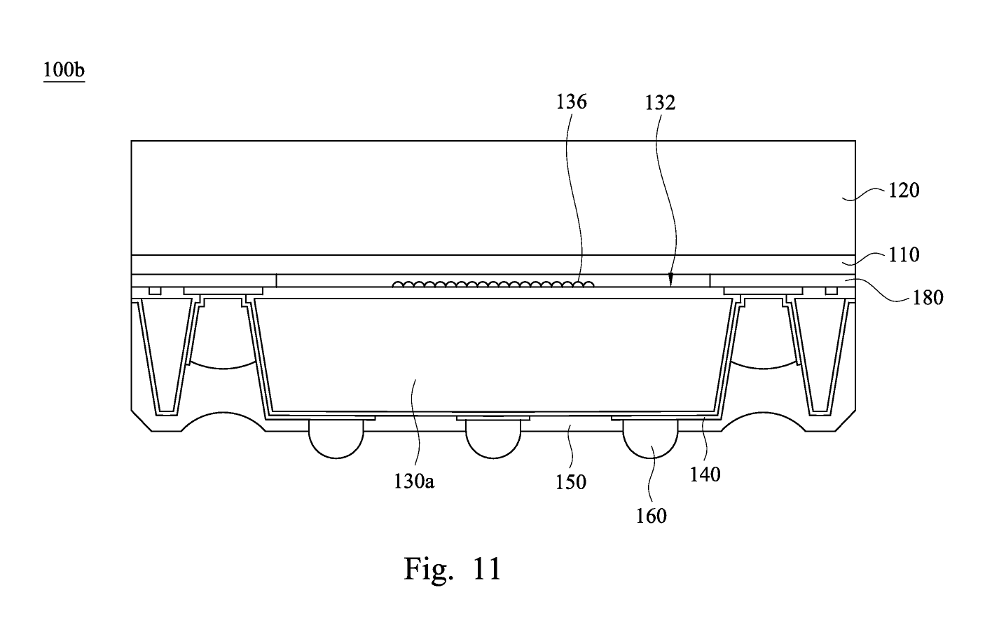

FIG. 11 is a cross-sectional view of a sub-semiconductor element 100b according to one embodiment of the present invention. The difference between this embodiment and the embodiment shown in FIG. 10A is that the first surface 132 of the chip 130a has a dam element 180 that surrounds the image sensing element 136. In this embodiment, when the temporary bonding layer 110 is used to adhere the carrier 120 to the first surface 132 of the wafer 130 (see FIG. 2), the temporary bonding layer 110 may be adhered to the dam element 180, such that the image sensing elements 136 are covered by the temporary bonding layer 110. When UV light irradiates the temporary bonding layer 110 to eliminate the adhesion of the temporary bonding layer 110, the carrier 120 can be removed from the temporary bonding layer 110, and the temporary bonding layer 110 can be removed from the dam element 180. Moreover, when the sub-semiconductor element 100b undergoes a dicing process shown in FIG. 4, a semiconductor element including the sub-semiconductor element 100b may be diced from the dam element 180 to the carrier 120.

The dam element 180 may be formed on the wafer 130 (see FIG. 2) by a photolithography process. The dam element 180 may be made of a material including epoxy, but the present invention is not limited in this regard.

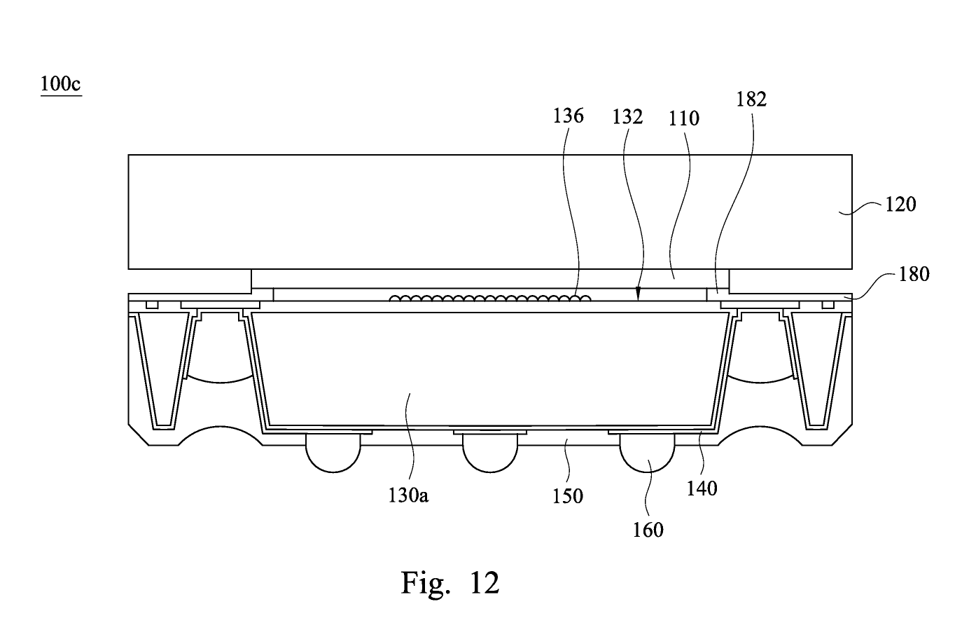

FIG. 12 is a cross-sectional view of a sub-semiconductor element 100c according to one embodiment of the present invention. The difference between this embodiment and the embodiment shown in FIG. 11 is that a surface of the dam element 180 opposite to the first surface 132 has a protruding portion 182. In this embodiment, when the temporary bonding layer 110 is used to adhere the carrier 120 to the first surface 132 of the wafer 130 (see FIG. 2), the temporary bonding layer 110 may be adhered to the protruding portion 182, such that the image sensing elements 136 are covered by the temporary bonding layer 110. When UV light irradiates the temporary bonding layer 110 to eliminate the adhesion of the temporary bonding layer 110, the carrier 120 can be removed from the temporary bonding layer 110, and the temporary bonding layer 110 can be removed from the protruding portion 182. The material of the protruding portion 182 may be the same as or different from that of the dam element 180.

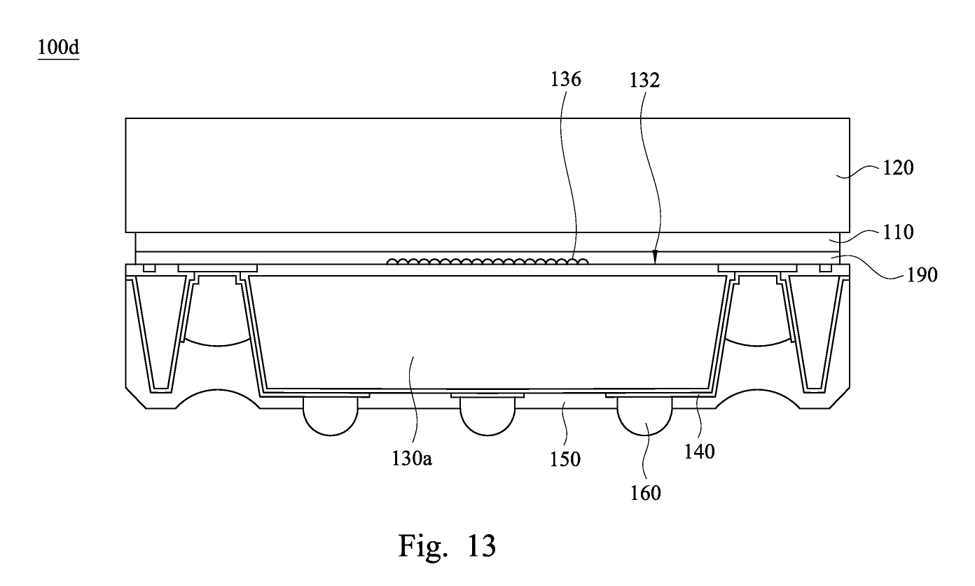

FIG. 13 is a cross-sectional view of a sub-semiconductor element 100d according to one embodiment of the present invention. As shown in FIG. 2 and FIG. 13, the difference between this embodiment and the embodiment shown in FIG. 10A is that a protection layer 190 is formed on the first surface 132 of the wafer 130. After the wafer 130 is diced to form the chip 130a, the image sensing element 136 on the chip 130a is covered by the protection layer 190. In this embodiment, when the temporary bonding layer 110 is used to adhere the carrier 120 to the first surface 132 of the wafer 130, the temporary bonding layer 110 may be adhered to the protection layer 190. When UV light irradiates the temporary bonding layer 110 to eliminate the adhesion of the temporary bonding layer 110, the carrier 120 can be removed from the temporary bonding layer 110, and the temporary bonding layer 110 can be removed from the protection layer 190.

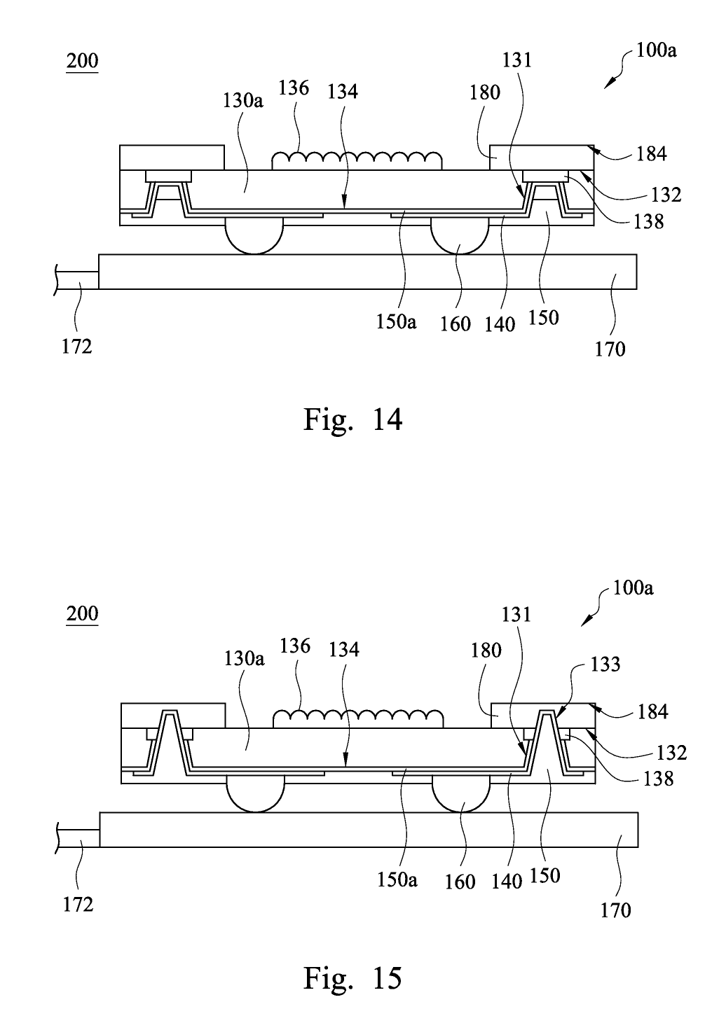

FIG. 14 is an example of the semiconductor device 200 shown in FIG. 9. The semiconductor device 200 includes the chip 130a, an isolation layer 150a, the redistribution layer 140, the insulating layer 150, and the conductive structure 160. The chip 130a has an electrical pad 138, a concave hole 131, the first surface 132, and the second surface 134 opposite to the first surface 132. The electrical pad 138 is located on the first surface 132. The concave hole 131 is located in the second surface 134. The first surface 132 of the chip 130a has the image sensing element 136. The isolation layer 150a is located on the second surface 134 and a side wall of the concave hole 131, such that the electrical pad 138 is exposed through the concave hole 131 and the isolation layer 150a. The redistribution layer 140 is located on the isolation layer 150a and the electrical pad 138, such that the redistribution layer 140 is electrically connected to the electrical pad 132. The insulating layer 150 is located on the redistribution layer 140, and a portion of the redistribution layer 140 is exposed through an opening of the insulating layer 150. The conductive structure 160 is located on the redistribution layer 140 that is in the opening of the insulating layer 150. The aforesaid structure is similar to the sub-semiconductor element 100a shown in FIG. 10A after the carrier 120 and the temporary bonding layer 110 are removed. In this embodiment, the semiconductor device 200 further includes a dam element 180. The dam element 180 is located on the first surface 132 of the chip 130a and surrounds the image sensing element 136.

The difference between the manufacturing method of the semiconductor device 200 shown in FIG. 14 and the embodiment shown in FIG. 1 is that step S2 of FIG. 1 further includes using the temporary bonding layer 110 (see FIG. 2) to adhere the surface 184 of the dam element 180 to the carrier 120 (see FIG. 2); and bonding the dam element 180 to the first surface 132 of the wafer 130 (see FIG. 2). Step S2 of FIG. 2 may further include forming the concave hole 131 in the second surface 134 of the wafer 130; forming the patterned isolation layer 150a on the second surface 134 of the wafer 130 and on the side wall of the concave hole 131, such that the electrical pad 138 of the wafer 130 is exposed through the concave hole 131 and the isolation layer 150a; forming the patterned redistribution layer 140 on the isolation layer 150a and the electrical pad 138, such that the redistribution layer 140 is electrically connected to the electrical pad 138; forming the patterned insulating layer 150 on the redistribution layer 140 to expose a portion of the redistribution layer 140; and forming the conductive structure 160 on the exposed redistribution layer 140, such that the conductive structure 160 is electrically connected to the electrical pad 138.

FIG. 15 is another example of the semiconductor device 200 shown in FIG. 9. The semiconductor device 200 includes the chip 130a, the isolation layer 150a, the redistribution layer 140, the insulating layer 150, and the conductive structure 160. The difference between this embodiment and the embodiment shown in FIG. 14 is that the electrical pad 138 and the dam element 180 have a sub-concave hole 133 that is communicated with the concave hole 131. As a result, the redistribution layer 140 may be located on the side wall of the sub-concave hole 133. In this embodiment, the redistribution layer 140 is located on the isolation layer 150a, the dam element 180, and the electrical pad 138, such that the redistribution layer 140 is electrically connected to the electrical pad 138.

The difference between the manufacturing method of the semiconductor device 200 shown in FIG. 15 and the embodiment shown in FIG. 14 is that step S2 of FIG. 1 further includes forming the sub-concave hole 133 that is communicated with the concave hole 131 in the electrical pad 138 and the dam element 180; and forming the patterned redistribution layer 140 on the isolation layer 150a, the electrical pad 138, and the dam element 180, such that the redistribution layer 140 is electrically connected to the electrical pad 138.

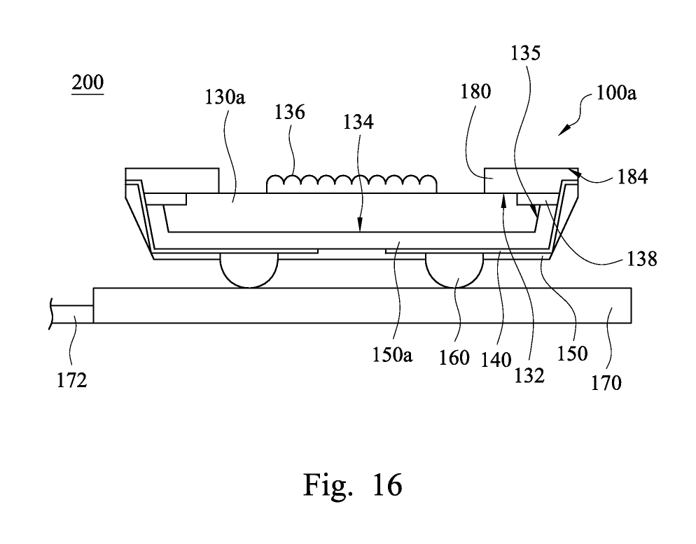

FIG. 16 is another example of the semiconductor device 200 shown in FIG. 9. The semiconductor device 200 includes the chip 130a, the isolation layer 150a, the redistribution layer 140, the insulating layer 150, and the conductive structure 160. The chip 130a has the electrical pad 138, a recess 135, the first surface 132, and the second surface 134 opposite to the first surface 132. The electrical pad 138 is located on the first surface 132. The side wall of the electrical pad 138 is exposed through the recess 135. The first surface 132 of the chip 130a has the image sensing element 136. The isolation layer 150a is located on the second surface 134 and the electrical pad 138 of the chip 130a, and the side wall of the electrical pad 138 is exposed through the isolation layer 150a. The redistribution layer 140 is located on the isolation layer 150a and the side wall of the electrical pad 138, such that the redistribution layer 140 is electrically connected to the electrical pad 138. The insulating layer 150 is located on the redistribution layer 140, and a portion of the redistribution layer 140 is exposed through an opening of the insulating layer 150. The conductive structure 160 is located on the redistribution layer 140 that is in the opening of the insulating layer 150.

The difference between the manufacturing method of the semiconductor device 200 shown in FIG. 16 and the embodiment shown in FIG. 1 is that the manufacturing method of the semiconductor device 200 shown in FIG. 16 further includes etching the wafer 130 (see FIG. 2) to form the recess 135, such that the side wall of the electrical pad 138 of the wafer 130 is exposed through the recess 135. Step S2 of FIG. 1 may further include forming the isolation layer 150a on the second surface 134 of the wafer 130 and on the side wall of the electrical pad 138; cutting off a portion of the isolation layer 150a that covers the side wall of the electrical pad 138 to expose the side wall of the electrical pad 138; forming the patterned redistribution layer 140 on the isolation layer 150a and the side wall of the electrical pad 138, such that the redistribution layer 140 is electrically connected to the electrical pad 138; forming the patterned insulating layer 150 on the redistribution layer 140 to expose a portion of the redistribution layer 140; and forming the conductive structure 160 on the exposed redistribution layer 140, such that the conductive structure 160 is electrically connected to the electrical pad 138.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A manufacturing method of a semiconductor device, the manufacturing method comprising:
(a) using a temporary bonding layer to adhere a carrier to a first surface of a wafer;
(b) forming a redistribution layer, an insulating layer, and a conductive structure on a second surface of the wafer opposite to the first surface, thereby forming a semiconductor element;
(c) dicing the semiconductor element from the insulating layer to the carrier, thereby making the semiconductor element become at least one sub-semiconductor element;
(d) using UV light to irradiate the sub-semiconductor element, thereby eliminating adhesion of the temporary bonding layer; and
(e) removing the carrier of the sub-semiconductor element.

2. The manufacturing method of claim 1, further comprising:
adhering the carrier of the semiconductor element to a cutting tape surrounded by a frame.

3. The manufacturing method of claim 1, further comprising:
bonding the sub-semiconductor element to a printed circuit board, thereby electrically connecting the conductive structure to the printed circuit board.

4. The manufacturing method of claim 1, wherein the first surface of the wafer has a plurality of image sensing elements, and the manufacturing method further comprises:
forming a protection layer on the first surface of the wafer, thereby covering the image sensing elements with the protection layer.

5. The manufacturing method of claim 1, wherein the first surface of the wafer has a plurality of image sensing elements, and step (a) further comprises:
controlling contact positions between the temporary bonding layer and the image sensing elements, thereby enabling top ends of image sensing elements to be in point contact with the temporary bonding layer.

6. The manufacturing method of claim 1, wherein the first surface of the wafer has a plurality of image sensing elements and a dam element, and step (a) further comprises:
adhering the temporary bonding layer to the dam element, thereby covering the image sensing elements with the temporary bonding layer.

7. The manufacturing method of claim 6, wherein step (c) further comprises:
dicing the semiconductor element from the dam element to the carrier.

8. The manufacturing method of claim 6, wherein a surface of the dam element opposite to the first surface has a protruding portion, and step (a) further comprises:
adhering the temporary bonding layer to the protruding portion, thereby covering the image sensing elements with the temporary bonding layer.

9. The manufacturing method of claim 1, further comprising:
removing the temporary bonding layer of the sub-semiconductor element.

10. The manufacturing method of claim 9, further comprising:
disposing a lens module on the sub-semiconductor element after the temporary bonding layer is removed.

11. The manufacturing method of claim 1, wherein step (a) further comprises:
using the temporary bonding layer to adhere a dam element to the carrier; and
bonding the dam element to the first surface of the wafer.

12. The manufacturing method of claim 11, wherein step (b) further comprises:
forming a concave hole in the second surface of the wafer; and
forming a patterned isolation layer on the second surface of the wafer and a side wall of the concave hole, thereby exposing an electrical pad of the wafer through the concave hole and the isolation layer.

13. The manufacturing method of claim 12, wherein step (b) further comprises:
forming the patterned redistribution layer on the isolation layer and the electrical pad, thereby electrically connecting the redistribution layer to the electrical pad.

14. The manufacturing method of claim 13, wherein step (b) further comprises:
forming the patterned insulating layer on the redistribution layer to expose a portion of the redistribution layer; and
forming the conductive structure on the exposed redistribution layer, thereby electrically connecting the conductive structure to the electrical pad.

15. The manufacturing method of claim 12, wherein step (b) further comprises:
forming a sub-concave hole that is communicated with the concave hole in the electrical pad and the dam element.

16. The manufacturing method of claim 15, wherein step (b) further comprises:
forming the patterned redistribution layer on the isolation layer, the electrical pad, and the dam element, such that the redistribution layer is electrically connected to the electrical pad.

17. The manufacturing method of claim 16, wherein step (b) further comprises:
forming the patterned insulating layer on the redistribution layer to expose a portion of the redistribution layer; and
forming the conductive structure on the exposed redistribution layer, thereby electrically connecting the conductive structure to the electrical pad.

18. The manufacturing method of claim 11, further comprising:
etching the wafer to form a recess, thereby exposing a side wall of an electrical pad of the wafer through the recess.

19. The manufacturing method of claim 18, wherein step (b) further comprises:
forming the isolation layer on the second surface of the wafer and the side wall of the electrical pad.

20. The manufacturing method of claim 19, wherein step (b) further comprises:
cutting off a portion of the isolation layer that covers the side wall of the electrical pad, so as to expose the side wall of the electrical pad; and
forming the patterned redistribution layer on the isolation layer and the side wall of the electrical pad, thereby electrically connecting the redistribution layer to the electrical pad.

21. The manufacturing method of claim 20, wherein step (b) further comprises:
forming the patterned insulating layer on the redistribution layer to expose a portion of the redistribution layer; and
forming the conductive structure on the exposed redistribution layer, thereby electrically connecting the conductive structure to the electrical pad.

22. The manufacturing method of claim 1, wherein step (c) further comprises:
forming a cut trench in the semiconductor element, thereby enabling an edge of the sub-semiconductor element to have the residual cut trench and a residual silicon substrate structure.

23. A semiconductor device, comprising:
a chip having an electrical pad, a concave hole, a first surface, and a second surface opposite to the first surface, wherein the electrical pad is located on the first surface, the concave hole is located in the second surface, and the first surface of the chip has an image sensing element;
an isolation layer located on the second surface and on a side wall of the concave hole, wherein the electrical pad is exposed through the concave hole and the isolation layer;
a redistribution layer located on the isolation layer and the electrical pad, wherein the redistribution layer is electrically connected to the electrical pad;
an insulating layer located on the redistribution layer, wherein a portion of the redistribution layer is exposed through an opening of the insulating layer; and
a conductive structure located on the redistribution layer that is in the opening of the insulating layer.

24. The semiconductor device of claim 23, further comprising:
a dam element located on the first surface and surrounding the image sensing element.

25. The semiconductor device of claim 24, wherein the electrical pad and the dam element have a sub-concave hole that is communicated with the concave hole.

26. The semiconductor device of claim 25, wherein the redistribution layer is located on the isolation layer, the dam element, and the electrical pad, such that the redistribution layer is electrically connected to the electrical pad.

27. The semiconductor device of claim 23, further comprising:
a protection layer located on the first surface of the chip and covering the electrical pad and the image sensing element.

28. The semiconductor device of claim 23, wherein an edge of the chip has a residual cut trench and a residual silicon substrate structure, and the silicon substrate structure is between the cut trench and the concave hole.

29. A semiconductor device, comprising:
a chip having an electrical pad, a recess, a first surface, and a second surface opposite to the first surface, wherein the electrical pad is located on the first surface, a side wall of the electrical pad is exposed through the recess, and the first surface of the chip has an image sensing element;
an isolation layer located on the second surface and the electrical pad, wherein the side wall of the electrical pad is exposed through the isolation layer;
a redistribution layer located on the isolation layer and on the side wall of the electrical pad, wherein the redistribution layer is electrically connected to the electrical pad;
an insulating layer located on the redistribution layer, wherein a portion of the redistribution layer is exposed through an opening of the insulating layer; and
a conductive structure located on the redistribution layer that is in the opening of the insulating layer.
